(19) United States
(12) Patent Application Publication
(10) Pub. No.: US 2024/0063216 A1
(43) Pub. Date: Feb. 22, 2024

(54) SEMICONDUCTOR DEVICE AND ELECTRONIC DEVICE

(71) Applicant: Infineon Technologies AG, Neubiberg (DE)

(72) Inventors: Digvijay Raghunathan, Munchen (DE); Anton Mauder, Kolbermoor (DE)

(21) Appl. No.: 18/364,494

(22) Filed: Aug. 3, 2023

(30) Foreign Application Priority Data
Aug. 16, 2022 (DE) 102022120578.9

(51) Int. Cl. H01L 27/06; H01L 29/861; H01L 29/739; H01L 29/78

(52) U.S. Cl. CPC H01L 27/0629; H01L 27/0664; H01L 29/8611; H01L 29/7398; H01L 29/7827; H02M 3/003

(57) ABSTRACT

A semiconductor device includes: a transistor formed in a first semiconductor layer stack; a diode formed in a second semiconductor layer stack, the diode including an anode metal layer; and a carrier. The transistor and the diode are mounted to the carrier. A terminal of the transistor is electrically connected to the carrier, and the anode metal layer is in direct contact with the carrier.

### TECHNICAL FIELD

The present disclosure is related to a semiconductor device, in particular a semiconductor device comprising a diode.

### BACKGROUND

Semiconductor devices, e.g. converter circuits comprising an active switch may comprise diodes for improving the characteristics thereof. Attempts are being made to improve a combination of such active switches with a diode.

### SUMMARY

It is an object of the present invention to provide an improved semiconductor device. According to embodiments, the above object is achieved by the claimed matter according to the independent claims. Further developments are defined in the dependent claims.

According to embodiments, a semiconductor device comprises a transistor formed in a first semiconductor layer stack, a diode formed in a second semiconductor layer stack, the diode comprising an anode metal layer, and a carrier. The transistor and the diode are mounted to the carrier. A terminal of the transistor is electrically connected to the carrier, and the anode metal layer is in direct contact with the carrier. The carrier may be a metallic carrier. The carrier may comprise a metal layer.

For example, the second semiconductor layer stack may consist of semiconductor layers that do not form part of the first semiconductor layer stack. To be more specific, the transistor and the diode may be formed of semiconductor layers that are separate from each other. For example, the transistor and the diode do not share common semiconductor layers.

According to embodiments, the terminal of the transistor may be in direct contact with the (metallic) carrier.

For example, the transistor may be a MOSFET and the terminal of the transistor is a drain terminal. By way of further example, the MOSFET may be an n-channel MOSFET.

According to further implementations, the transistor may be an IGBT and the terminal of the transistor is a collector terminal. By way of example, the IGBT may be an re-channel IGBT.

According to embodiments, the diode may comprise a low doped drift region between an anode region and a cathode region. A conductivity type of the drift region may be different from a conductivity type of a drift zone of the transistor.

For example, the diode may comprise a p-doped substrate layer and an n-doped cathode layer formed over the p-doped substrate layer. The diode may further comprise a p-doped drift region in the p-doped substrate layer.

According to an implementation, the n-doped cathode layer is arranged in a central portion of the diode at a first main surface of the second semiconductor layer stack. The diode may further comprise an edge termination structure horizontally surrounding the central portion.

For example, the edge termination structure may comprise an n-doped ring portion arranged at the first main surface of the second semiconductor layer stack and isolated from the n-doped cathode layer.

According to a further example, the edge termination structure may comprise an n-doped termination portion having a decreasing doping concentration in a direction facing away from the central portion and arranged at the first main surface of the second semiconductor layer stack.

For example, the diode may comprise an n-doped substrate layer and an n-doped cathode layer formed over the n-doped substrate layer. The diode may further comprise an n-doped drift region in the n-doped substrate layer.

For example, the n-doped cathode layer may be arranged in a central portion of the diode at a first main surface of the second semiconductor layer stack. The diode may further comprise an edge termination structure that horizontally surrounds the central portion.

According to embodiments, the edge termination structure may comprise a p-doped region extending from the first main surface to a second main surface of the second semiconductor layer stack, the p-doped edge region being isolated from the n-doped cathode layer.

According to embodiments, the semiconductor device may further comprise a p-doped ring structure arranged adjacent to a first or a second main surface of the n-doped drift region. The p-doped ring structure is isolated from the p-doped anode region.

According to further embodiments, a semiconductor device comprises a transistor formed in a first semiconductor layer stack, a diode formed in a second semiconductor layer stack, the second semiconductor layer stack consisting of semiconductor layers that do not form part of the first semiconductor layer stack, and a carrier. The transistor and the diode are mounted to the carrier, and a transistor terminal and a diode anode terminal are electrically connected to the carrier. The carrier may be a metallic carrier. The carrier may comprise a metal layer.

According to embodiments described herein, the semiconductor device may further comprise an insulating material between the diode and the (metallic) carrier. The insulating material may be arranged between the diode and the transistor. The diode may be electrically connected to the (metallic) carrier through via openings in the insulating material.

For example, the semiconductor device may further comprise a first galvanic interconnect material for electrically connecting a cathode terminal of the diode.

Still further, the semiconductor device may additionally comprise a second galvanic interconnect material for electrically connecting the anode terminal of the diode to the (metallic) carrier.

An electronic device comprises the semiconductor device as defined above. For example, the electronic device may be selected from a buck converter and a DC-DC converter.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows an example of a semiconductor device according to embodiments.

FIG. 2A shows a vertical cross-sectional view of the semiconductor device according to further embodiments.

FIG. 2B shows a vertical cross-sectional view of another example of a semiconductor device.

FIG. 3A illustrates elements of the diode forming a component of a semiconductor device according to embodiments.

FIG. 3B illustrates elements of a further diode forming a component of a semiconductor device according to embodiments.

FIG. 3C is a top-view of a diode forming a component of a semiconductor device according to embodiments.

FIG. 4 shows a cross-sectional view of another diode forming a component of the semiconductor device according to embodiments.

FIG. 5 illustrates a vertical cross-sectional view of a semiconductor device according to further embodiments.

FIG. 6 shows a schematic diagram of an electronic device.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer”, “substrate” or “semiconductor substrate” used in the following description may include any semiconductor-based structure that has a semiconductor surface. Wafer and structure are to be understood to include silicon, silicon-on-insulator (SOU, silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide. According to other embodiments, silicon carbide (SiC), gallium nitride (GaN) or gallium oxide (Ga₂O₃) may form the semiconductor substrate material.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The terms “lateral” and “horizontal” as used in this specification intends to describe an orientation parallel to a first surface of a substrate or semiconductor body. This can be for instance the surface of a wafer or a die.

The term “vertical” as used in this specification intends to describe an orientation which is arranged perpendicular to the first surface of a substrate or semiconductor body.

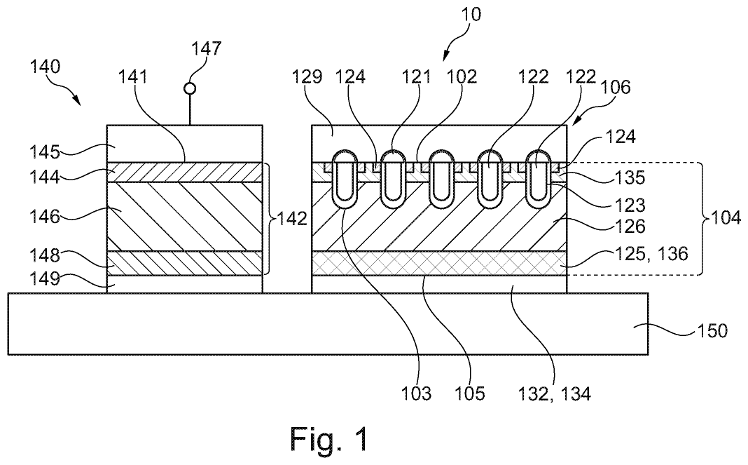

FIG. 1 shows a cross-sectional view of a semiconductor device 10 according to embodiments. The semiconductor device 10 comprises a transistor 106 which is formed in a first semiconductor layer stack 104 and a diode 140 which is formed in a second semiconductor layer stack 142. The first semiconductor layer stack 104 may be formed in a first semiconductor body. The second semiconductor layer stack 142 may be formed in a second semiconductor body. The first and the second semiconductor body may be separate semiconductor bodies. The diode 140 comprises an anode metal layer 149. The semiconductor device 10 further comprises a carrier 150. The transistor 106 and the diode 140 are mounted to the carrier 150. For example, both the transistor 106 and the diode 140 are mounted to the same side, e.g. an upper side, of the carrier 150. A terminal 132, 134 of the transistor is electrically connected to the carrier 150. Further, the anode metal layer 149 is direct contact with the carrier 150. The carrier 150 may comprise a lead frame or a DCB (“direct copper bonding”) substrate. The thickness of the carrier 150 may be greater than a thickness of the first semiconductor layer stack 104 and/or of the second semiconductor layer stack 142. According to some embodiments, the carrier 150 may have a thickness of at least three times the thickness of the first semiconductor layer stack 104 and/or of the second semiconductor layer stack 142. For example, the carrier 150 may have a thickness of at least 0.5 mm. The carrier 150 may provide mechanical stability to the semiconductor device 10. For example, the base frame may contribute at least 80% of the mechanical stiffness of the semiconductor device 10.

For example, the carrier 150 may comprise a metal or be made of metal. For example, the carrier 150 may comprise a metal layer. In the following, the carrier 150 will be referred to as “metal carrier” or “metallic carrier”. For example, the term “metal carrier” may relate to any kind of substrate including a metal layer. The metal layer may be patterned. According to further implementations, the metal carrier may as well be or comprise a galvanic interconnect structure.

The first semiconductor layer stack 104 may be separate from the second semiconductor layer stack 142. For example, the diode 140 and the transistor 106 do not share common semiconductor layers. For example, an air gap or an insulating material may be arranged between the first semiconductor layer stack 104 and the second semiconductor layer stack 142.

The term “diode” may generally relate to any kind of semiconductor structure comprising a pn junction. For example, the diode 140 may be formed in a p-doped substrate. For example, in this case, a portion of the substrate may be n-doped to form a cathode layer 144 of the diode 140. For example, a drift region 146 which may have a lower doping concentration than the anode region 148 may be arranged between the cathode layer 144 and the anode region 148. For example, when the diode 140 is formed in a p-doped substrate, the drift region 146 may be p-doped. Further implementations of the diode 140 may be realized and will be discussed later.

An anode metal layer 149 is directly adjacent to the anode region 148 or anode layer. Further, as is e.g. illustrated in FIG. 1, the anode metal layer 149 may be in direct contact with a metallic carrier 150. A cathode metal layer 145 may be formed in electrical contact which the cathode layer 144. For example, depending on implementations, the cathode layer 145 may cover the entire first main surface 141 of the second semiconductor layer stack 142. Alternatively, the cathode metal layer 145 may be arranged only over a portion of the first main surface 141 of the second semiconductor layer stack. A cathode terminal 147 is electrically connected to the cathode metal layer 145.

The transistor 106 may be implemented in many ways. For example, the transistor 106 may implemented as a MOSFET, e.g. as a n-channel MOSFET. According to further implementations, the transistor 106 may as well be implemented as an IGBT, e.g. an n-channel IGBT. For example, as is illustrated in FIG. 1, a MOSFET 106 may comprise a source region 124, a drain region 125, a body region 135 and a gate electrode 122. For example, as is illustrated in FIG. 1, the gate electrode 122 may be arranged in gate tranches that extend in a vertical direction from a first main surface 102 of the first semiconductor layer stack 104. The gate trenches further extend in a horizontal direction, e.g. perpendicular with respect to the depicted plane of the cross-sectional view. A drift zone 126 may be arranged between the body region 135 and the drain region 125. When a suitable voltage is applied to the gate electrode 122, a conductive channel may be formed at an interface between the gate dielectric 123 and the body region 135. A current may be generated between the source region 124 and the drain region 125 via the body region 135 and, optionally, the drift zone 126.

For example, the transistor 106 may be implemented as a MOSFET. Accordingly, the source region and the drain region may be of a first conductivity type, and the body region 135 may be of a second conductivity type. For example, in an re-channel MOSFET, the first conductivity type may be n-type, and in a p-channel MOSFET, the first conductivity type may be p-type.

According to further implementations, the transistor 106 may be implemented as an IGBT. In this case, the source region 124 acts as an emitter. Further, a collector region 136 is arranged adjacent to a second main surface 105 of the first semiconductor layer stack 104. The collector region 136 is doped with a conductivity type different from the conductivity type of the emitter region. For example, when the emitter region is n-doped, the collector region 136 is p-doped and vice versa.

As is illustrated in FIG. 1, a drain metallization or drain terminal 132 is arranged directly adjacent to the drain region 125. In case of an IGBT, a transistor terminal 134 is arranged adjacent to the collector region 136. The transistor terminal 134 adjacent to the collector region 136 or the drain metallization 132 is electrically connected to the metal carrier 150. For example, the drain metallization may be in direct contact with the metallic carrier 150. According to further implementations, the drain metallization may be connected to the metal carrier by means of a further wiring.

In the following, the second terminal of the transistor 106 will be referred to as a “drain terminal”. This term likewise comprises a collector terminal 136 in case the transistor is implemented as an IGBT.

For example, the embodiment of FIG. 1 may be suitable for high voltage transistors, which may be implemented in a Si or SiC substrate.

Further, the embodiment of FIG. 1 may be suitable for IGBTs operated at high voltages. For example, the high voltage transistors or IGBTs may be operated at voltages higher than 300 V.

According to all embodiments described herein, the front side connections of the diode 140 and the transistor 106 are connected independently from each other to the outside. For example, the diode 140 and/or the transistor 106 may be attached to the metallic carrier 150 by diffusion soldering and/or by sintering. For example, diffusion soldering may be accomplished using AuSn/NiSn as a bonding material, sintering may employ silver or copper as a bonding material.

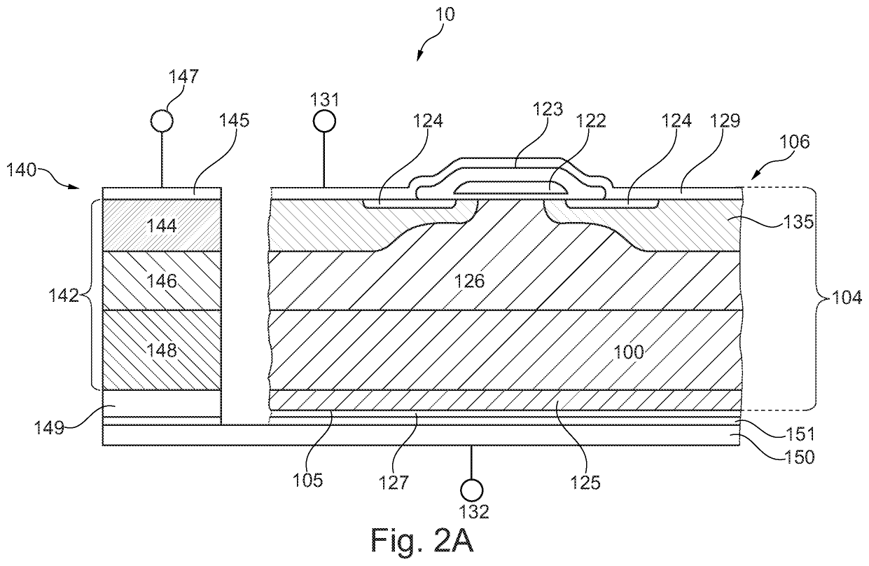

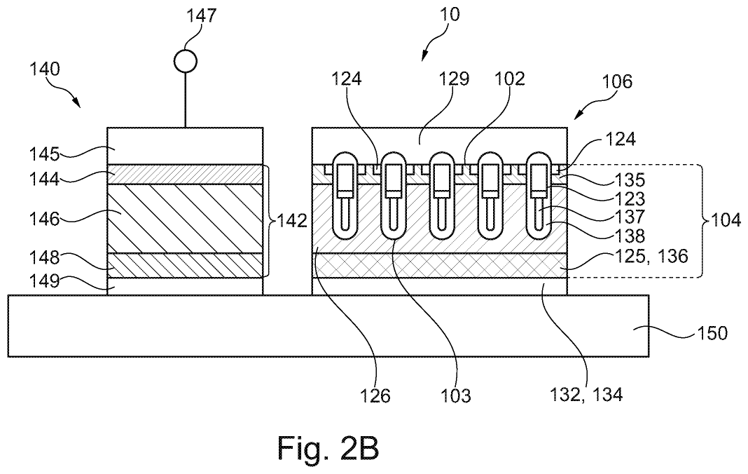

As is to be clearly understood, the transistor 106 may be implemented in any arbitrary manner. For example, as is illustrated in FIG. 2A, the transistor 106 may comprise a planar gate electrode 122, which is arranged over a first main surface 102 of the first semiconductor layer stack 104. The further components of the semiconductor device 10 illustrated in FIG. 2A, are similar to or identical with those shown in FIG. 1. Differing from the embodiment shown in FIG. 1, the gate electrode 122 is formed as a planar gate electrode over the first main surface 102 of the first semiconductor layer stack. As is further shown in FIG. 2A, the drain region 125 is arranged adjacent to a second main surface 105 of the first semiconductor layer stack.

FIG. 2B shows a cross-sectional view of a semiconductor device according to further embodiments. The semiconductor device of FIG. 2B is based on the semiconductor device shown in FIG. 1. In addition, the transistor 106 further comprises field plates 137, which are arranged in the drift region 126. The field plates and the gate electrodes 122 are arranged in gate trenches 103 extending the first main surface 102 of the first semiconductor layer stack in a vertical direction, for example. The further components of FIG. 2B are similar to or identical with the components illustrated in FIG. 1.

The embodiment of FIG. 2B may be suitable for low voltage transistors, e.g. up to 300 V.

In the following, cross-sectional views of the diode 140 will be discussed in more detail. In particular, different options of an edge termination structure will be illustrated.

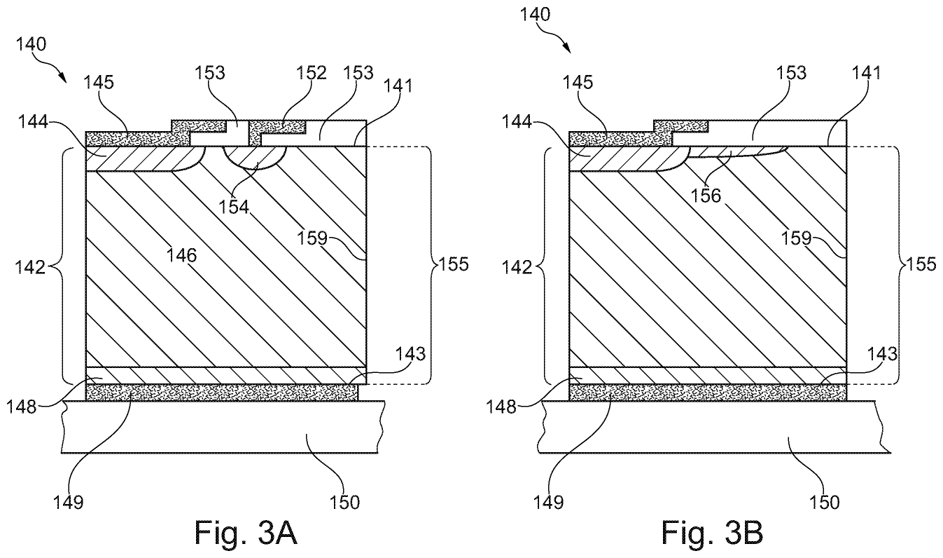

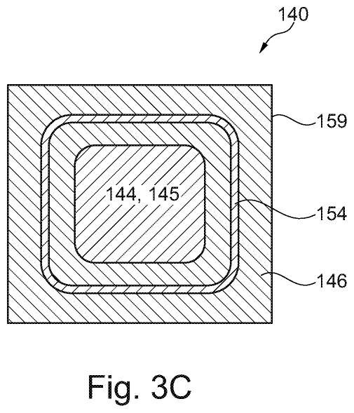

FIG. 3A shows a cross-sectional view of a diode 140. For example, the diode 140 shown in FIG. 3A may be formed in a p-doped substrate. An anode region 148 is adjacent to a second main surface 143 of the second semiconductor layer stack 142. The cathode layer 144 is formed in a central portion of the diode 140 at a first main surface 141 of the second semiconductor layer stack 142. The diode further comprises an edge termination structure that horizontally surrounds the central portion. For example, the edge termination structure may be implemented as a doped ring portion 154. The doped ring portion 154 may be n-doped. The ring portion 154 may be arranged in the p-doped substrate layer 155. For example, the doped ring portion 154 may be electrically connected to a field plate 152, which may be arranged over the first main surface 141 of the second semiconductor layer stack 142. The field plate 152 is insulated from e.g. the cathode metal layer 145 by means of a dielectric layer 153. The doped ring portion 154 may be isolated from the cathode layer 144 by means of portions of the drift region 146.

FIG. 3B shows a cross-sectional view of a diode 140 according to further embodiments. According to the embodiment of FIG. 3B, the termination portion 156 is arranged adjacent to the first main surface 141 of the second semiconductor layer stack. The termination portion 156 comprises n-doped semiconductor material. The termination portion 156 may be in contact with the cathode layer 144. A doping concentration of the termination portion 156 decreases gradually towards the chip edge. FIGS. 3A and 3B also show the dicing line 159 at which adjacent chips are singulated.

FIG. 3C shows an example of a top-view of the diode 140. As is shown, the cathode and the cathode metal layer 145 are arranged in a central portion of the diode 140. The doped ring portion 154 surrounds the cathode layer 144 and the cathode metal layer 145. The doped ring portion 154 is spaced from a dicing line 159 and from the cathode layer 144 or the cathode metal layer 145.

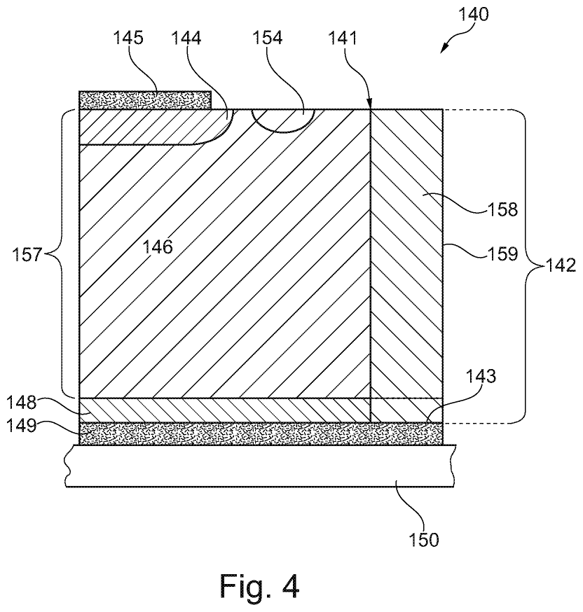

FIG. 4 shows a cross-sectional view of a diode 140 that may be a component of the semiconductor device 10 according to further embodiments. Differing from embodiments that are e.g. illustrated in FIGS. 3A and 3B, the diode 140 of FIG. 4 is formed in an n-doped substrate layer 157. Accordingly, the drift region 146 is n-doped, wherein the drift region 146 is arranged between the cathode layer 144 and the anode region 148. As is further shown, in this case, a separating diffusion portion may be arranged adjacent to the dicing line 159. The separating diffusion portion may implement a p-doped edge region 158, which extends from the first main surface 141 of the second semiconductor layer stack 142 to the second main surface 143 of the semiconductor layer stack 142.

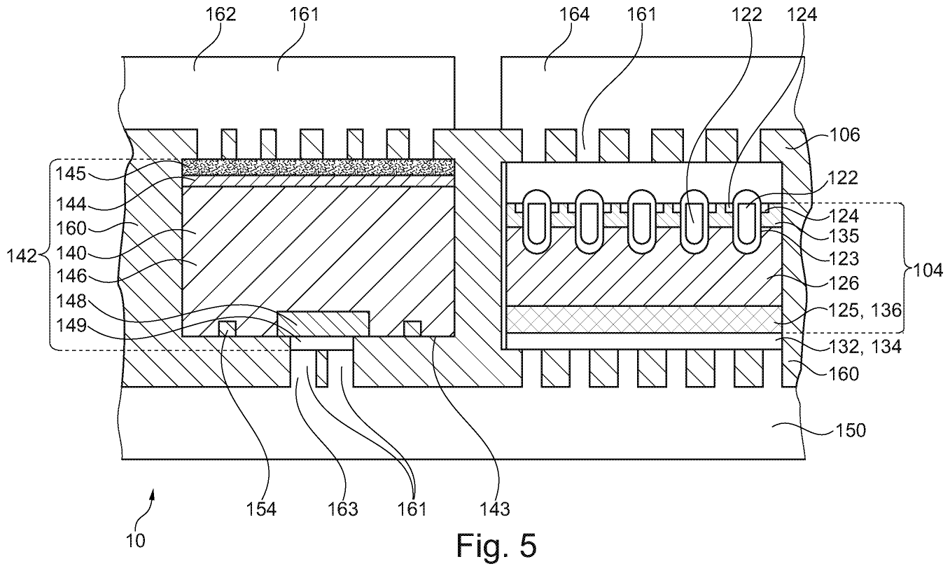

As is further shown in FIG. 4, the cathode layer 144 may be arranged in a central portion of the diode 140. Further, the anode region 148 or anode layer extends over the whole surface 143 of the diode 140. Moreover, a doped ring portion 154, which may be p-doped may be arranged adjacent to the first main surface 141 of the second semiconductor layer stack 142. According to alternative implementations, the cathode layer 144 may be arranged over the entire first main surface 141 of the second semiconductor layer 142, and the p-doped edge region 158 may be dispensed with. Further, the anode region 148 may be arranged only in the central portion of the diode 140. Moreover, a doped ring portion 154 may be arranged adjacent to the second main surface 143. This will be illustrated in more detail in FIG. 5 below.

FIG. 5 shows a semiconductor device 10, comprising a diode 140 and a transistor 106. The transistor 106 is formed in a first semiconductor layer stack 104 and may comprise components that are similar to or identical with components with those illustrated in FIG. 1 and discussed hereinbefore. Further, the diode 140 is formed in a second semiconductor layer stack 142. The second semiconductor layer stack 142 is spaced apart from the first semiconductor layer stack 104. Moreover, the transistor 106 and the diode 140 do not share common semiconductor layers. The semiconductor device 10 further comprises a metallic carrier 150. The transistor 106 and the diode 140 are mounted to the metallic carrier 150. Transistor terminal 134 and a diode terminal 149 are electrically connected to the metallic carrier 150.

For example, as is shown in FIG. 5, the diode anode terminal is electrically connected to the metallic carrier 150 via openings 161 in an insulating material 160. The insulating material 160 completely encloses the diode 140 and comprises via openings 161 for electrically connecting the anode terminal 149 and for electrically connecting the cathode terminal 145. The insulating material 160 is also arranged between the diode 140 and the transistor 106. For example, the insulating material 160 may comprise one or more layers of an oxide and/or nitride, e.g. silicon oxide or silicon nitride. Alternatively or additionally, the insulating material 160 may comprise a material used for attaching the diode 140 to the metallic carrier 150. In a first example, the insulating material 160 may comprise a polymer, e.g. an imide or a resin as epoxy. In this case, the diode 140 may be attached to the metallic carrier 150 through a molding process. In a second example, the insulating material 160 may comprise a foil, e.g. a die attach foil (also known as DAF tape). In this case, the diode 140 may be attached to the metallic carrier 150 via the foil. For example, the semiconductor device may comprise a first galvanic interconnect material 162 for electrically connecting the cathode terminal 145 of the diode. Moreover, the semiconductor device may further comprise a second galvanic interconnect material 163 for electrically connecting the anode terminal 149 of the diode to the metallic carrier 150.

Accordingly, the insulating material 160 may also be present between the diode 140 and the metallic carrier 150. Further, the insulating material 160 may as well be present between the transistor 106 and the metallic carrier 150. FIG. 5 also shows a doped ring portion 154 which is arranged adjacent to the second layer surface 143 of the second semiconductor layer stack.

Due to the specific arrangement in which the transistor and the diode are mounted to the metallic carrier, there is no need to electrically connect the anode terminal to the drain terminal of the transistor 106 by means of a wire. As a result, stray inductances at the leads of power devices and the diode may be avoided. As a consequence, clamping may be made more effective and a loss of efficiency may be reduced. The specific concept described herein may be implemented in a cost-efficient way. Moreover, the high switching speed of the switch may be maintained. Hence, additional losses from the switch may be avoided. Further, a part of the switching energy may be fed back to the input/output.

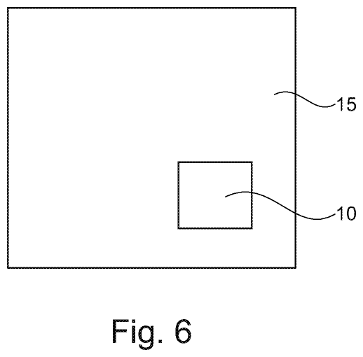

FIG. 6 shows a schematic diagram of an electronic device 15 according to embodiments. The electronic device 15 comprises the semiconductor device 10, which has been explained herein above. For example, the electronic device 15 may be a buck converter or a DC converter.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A semiconductor device, comprising:
a transistor formed in a first semiconductor layer stack;
a diode formed in a second semiconductor layer stack, the diode comprising an anode metal layer; and
a carrier,
wherein the transistor and the diode are mounted to the carrier,
wherein a terminal of the transistor is electrically connected to the carrier,
wherein the anode metal layer is in direct contact with the carrier.

2. The semiconductor device of claim 1, wherein the second semiconductor layer stack comprises semiconductor layers that do not form part of the first semiconductor layer stack.

3. The semiconductor device of claim 1, wherein the terminal of the transistor is in direct contact with the carrier.

4. The semiconductor device of claim 1, wherein the transistor is a MOSFET and the terminal of the transistor is a drain terminal.

5. The semiconductor device of claim 1, wherein the transistor is an IGBT and the terminal of the transistor is a collector terminal.

6. The semiconductor device of claim 1, wherein the diode comprises a low doped drift region between an anode region and a cathode region, and wherein a conductivity type of the drift region is different from a conductivity type of a drift zone of the transistor.

7. The semiconductor device of claim 1, wherein the diode comprises a p-doped substrate layer and an n-doped cathode layer formed over the p-doped substrate layer, and wherein the semiconductor device further comprises a p-doped drift region in the p-doped substrate layer.

8. The semiconductor device of claim 7, wherein the n-doped cathode layer is arranged in a central portion of the diode at a first main surface of the second semiconductor layer stack, and wherein the diode further comprises an edge termination structure horizontally surrounding the central portion.

9. The semiconductor device of claim 8, wherein the edge termination structure comprises an n-doped ring portion arranged at the first main surface of the second semiconductor layer stack and isolated from the n-doped cathode layer.

10. The semiconductor device of claim 8, wherein the edge termination structure comprises an n-doped termination portion having a decreasing doping concentration in a direction facing away from the central portion and arranged at the first main surface of the second semiconductor layer stack.

11. The semiconductor device of claim 1, wherein the diode comprises an n-doped substrate layer and a n-doped cathode layer formed over the n-doped substrate layer, and wherein the semiconductor device further comprises an n-doped drift region in the n-doped substrate layer.

12. The semiconductor device of claim 11, wherein the n-doped cathode layer is arranged in a central portion of the diode at a first main surface of the second semiconductor layer stack, and wherein the diode further comprises an edge termination structure horizontally surrounding the central portion.

13. The semiconductor device of claim 12, wherein the edge termination structure comprises a p-doped region extending from the first main surface to a second main surface of the second semiconductor layer stack, and wherein the p-doped edge region is isolated from the n-doped cathode layer.

14. The semiconductor device of claim 12, further comprising a p-doped ring structure arranged adjacent to a first or a second main surface of the n-doped drift region.

15. An electronic device comprising the semiconductor device of claim 1.

16. The electronic device of claim 15, wherein the electronic device is a buck converter or a DC-DC converter.

17. A semiconductor device, comprising:
a transistor formed in a first semiconductor layer stack;
a diode formed in a second semiconductor layer stack, the second semiconductor layer stack comprising semiconductor layers that do not form part of the first semiconductor layer stack; and
a carrier,
wherein the transistor and the diode are mounted to the carrier,
wherein a transistor terminal and a diode anode terminal are electrically connected to the carrier.

18. The semiconductor device of claim 17, further comprising an insulating material between the diode and the carrier, wherein the insulating material is also arranged between the diode and the transistor, and wherein the diode is electrically connected to the carrier through via openings in the insulating material.

19. The semiconductor device of claim 18, further comprising a first galvanic interconnect material for electrically connecting a cathode terminal of the diode.

20. The semiconductor device of claim 18, further comprising a second galvanic interconnect material for electrically connecting the anode terminal of the diode to the carrier.

21. The semiconductor device of claim 17, wherein the carrier comprises a metal layer.

22. An electronic device comprising the semiconductor device of claim 21.

23. The electronic device of claim 22, wherein the electronic device is a buck converter or a DC-DC converter.
